(19) United States
(12) Patent Application Publication
(10) Pub. No.: US 2016/0291458 A1
(43) Pub. Date: Oct. 6, 2016

(54) METHOD INTEGRATING TARGET OPTIMIZATION AND OPTICAL PROXIMITY CORRECTION

(71) Applicants: Daquan He, Shanghai (CN); Fang Wei, Shanghai (CN); Jun Zhu, Shanghai (CN); Yukun Lv, Shanghai (CN); Xusheng Zhang, Shanghai (CN)

(72) Inventors: Daquan He, Shanghai (CN); Fang Wei, Shanghai (CN); Jun Zhu, Shanghai (CN); Yukun Lv, Shanghai (CN); Xusheng Zhang, Shanghai (CN)

(21) Appl. No.: 14/753,192

(22) Filed: Jun. 29, 2015

(30) Foreign Application Priority Data
Mar. 30, 2015 (CN) 201510144598.6

(51) Int. Cl. G03F 1/36; G06F 17/50

(52) U.S. Cl. CPC G03F 1/36; G06F 17/5009

(57) ABSTRACT

A method integrating target optimization and optical proximity correction including: fragmenting sides of a target pattern in the metal layer to form a plurality of fragments; simulating the target pattern and calculating image log slope of each fragment; calculating a target pattern optimal parameter for each fragment which is a product of three parameters including the image log slope, overlap ratio of the target pattern and a via pattern in a via layer, and critical dimension; optimizing the target pattern based on the target pattern optimal parameter; preforming optical proximity correction to the optimized target pattern; determining whether the corrected target pattern meets requirements; if yes, ending the target optimization and optical proximity correction; otherwise, using the corrected target pattern as a current target pattern and iterate from the step of simulating the target pattern and calculating image log slope of each fragment.

### CROSS-REFERENCE TO RELATED APPLICATION

This application claims the priority benefit of China application Serial No. 201510144598.6, filed Mar. 30, 2015. All disclosure of the China application is incorporated herein by reference.

### FIELD OF THE INVENTION

The present invention relates to the field of semiconductor manufacturing technology, particularly to a method integrating target optimization and optical proximity correction.

### BACKGROUND OF THE INVENTION

Nowadays, the industry is continuing to shrink critical dimension of semiconductors according to Moore's Law, however, the optical wavelength of the lithography process has been maintained at 193 nm and stand still. Therefore, pattern features of a silicon wafer surface imaging by using sub-wavelength lithography process, which is used for design pattern less than the exposure wavelength, could experience serious inconsistency when compare to the original layout, such as corner rounding, line-end shortening and line-width deviation. Thus, since photolithographic imaging could be affected by various factors, it is difficult to transfer all designed features of the pattern to the wafer reliably when using photolithography process even if the process carried out in accordance with established layout design rules. Especially, the pattern of a two-dimensional structure is more susceptible in the case of the lithography process fluctuates and will cause serious process defects.

This graphic distortion between the original layout and the pattern generated on the wafer surface is known as optical proximity effect (OPE). OPE will result deviations in electrical characteristics, which could affect the performance of the final products and reduces the production yield of integrated circuits. In order to mitigate and offset the OPE in the sub-wavelength lithography process, optical proximity correction (OPC) is widely used in the industry. Meanwhile, before performing the OPC, patterns lower process window usually will be adjusted or optimized in order to increase the overall process window. Existing target pattern adjustments or optimizations are using selective target size adjusting method, which specifically refers to the way that selects patterns need to be size adjusted and adjusts the patterns' size according to certain rules, such as patterns' density, to enlarge the process window. Generally, an intensive pattern has relatively large process window, while the process window of a less dense pattern of the same size is relatively small. Therefore, the size of the less dense pattern could be enlarged to improve the process window. FIG. 1 shows the existing overall process of target optimization and optical proximity correction method. First, the original layout (design pattern) is target adjusted or optimized based on certain rules, then the model-based OPC process is performed. Such the OPC process includes: fragmenting the adjusted or optimized target patterns according to certain rules; then, simulating result images of the target patterns, correcting according to Edge Placement Error (EPE) between the simulation contour of the target pattern and the contour of the target pattern; after correction, simulating again and comparing the simulation contour with the contour of the target pattern, iterating the aforementioned processes to obtain the final results of the optical proximity correction. However, the above mentioned method has the following defects:

On one hand, the rule-based target pattern adjustment or optimization is not effective for complex patterns of two-dimensional structure, as the pattern of two-dimensional structure is very sensitive to varying process conditions and it is difficult to handle process window problems of two-dimensional structure with simple rules.

On the other hand, when the selective target adjusting method is applied to patterns in the metal layer, although the overall process window of the metal layer can be improved by adjusting the line width or spacing of the metal wires, such as enlarging some of the isolated wires, or enlarging the spacing between wires, however this may cause localized interconnection failures between metal wires and the vias or the interconnection process window becomes smaller if without considering the area of the interconnection point of contact between the metal layer and the via layer. As shown in FIG. 2a, after the target pattern adjustment or optimization, the spacing between the metal wires 101 of the design pattern is increased, resulting in a portion of the via 102 being located outside the target pattern (shown in FIG. 2b). Then after preforming the OPC process (shown in FIG. 2c)and simulating the contour of the metal wires (shown in FIG. 2d), the overlap ratio of the metal wires and vias are relatively low, the upper and lower layers could not be aligned (overlay) properly, which may cause localized connection failure.

### SUMMARY OF THE INVENTION

The primary object of the invention is to propose an integrated target optimization and optical proximity correction method, which can be applied to two-dimensional patterns in the metal layer, so as to improve the process window as well as to overcome the defects of connection failure between the metal wires and vias.

To achieve the above object, the present invention provides a method integrating target optimization and optical proximity correction, the method comprises the following steps:

Step S01: inputting a design pattern, the design pattern includes patterns in at least a metal layer and a via layer;

Step S02: fragmenting sides of a target pattern in the metal layer to form a plurality of fragments;

Step S03: simulating the target pattern and calculating image log slope of each fragment;

Step S04: calculating a target pattern optimal parameter for each fragment, the target pattern optimal parameter is a product of three parameters including the image log slope of the fragment, the ratio of a portion of an overlap between the target pattern and a via pattern in the via layer which corresponds to the fragment to a portion of the via pattern which corresponds to the fragment; and a critical dimension of the fragment;

Step S05: optimizing the target pattern based on the target pattern optimal parameter for each fragment;

Step S06: preforming optical proximity correction to the optimized target pattern;

Step S07: determining whether the corrected target pattern meets requirements; if yes, ending the target optimization and optical proximity correction; otherwise, using the corrected target pattern as a. current target pattern and iterate from the step S03.

Preferably, the critical dimension of the fragment includes a line-width of the target pattern corresponding to the fragment and a spacing between the target pattern and its adjacent pattern corresponding to the fragment.

Preferably, the target pattern optimal parameter for each fragment includes a line-width parameter and a spacing parameter.

Preferably, in the step S05, the target pattern is optimized by moving each fragment according to a look-up table which constitutes the target pattern optimal parameters of each fragment.

Preferably, the step S05 comprises: establishing a look-up table recording retargeting values of the fragments with different combinations of line-width and spacing parameters; and moving each fragment the retargeting value corresponding to the line-width and the spacing parameter of the fragment recorded in the look-up table.

Preferably, in the step S04, the target pattern optimal parameter of each fragment is calculated based on a mid-point of the fragment.

Preferably, in the step S02, the target pattern is fragmented according to specified rules.

Preferably, the step S06 comprises: simulating the optimized target pattern (1^{st} iteration) or corrected pattern (other iterations); and moving each fragment based on an edge placement error between the simulation contour and the optimized target pattern.

Preferably, in the step S07, whether the corrected target pattern meets the requirements is determined through determining whether the edge placement error between the simulation contour of the corrected target pattern and the optimized target pattern is less than a predetermined threshold.

Preferably, in the step S06, the optimized target pattern is simulated based on a model which is the same as a model used in the step 03 for simulating the target pattern.

The present invention proposes an integrated target optimization and optical proximity correction method which utilizes a model-based approach in the target optimization process to achieve better expansibility, higher accuracy compared with other traditional rule-based target optimization method, and wider application to two-dimensional structures; moreover, it could reduce the sensitivity of localized pattern to varying process conditions, so as to improve the photolithographic process window.

### BRIEF DESCRIPTION OF THE DRAWINGS

FIG. 1 is a schematic diagram illustrating the conventional target optimization and optical proximity correction processes;

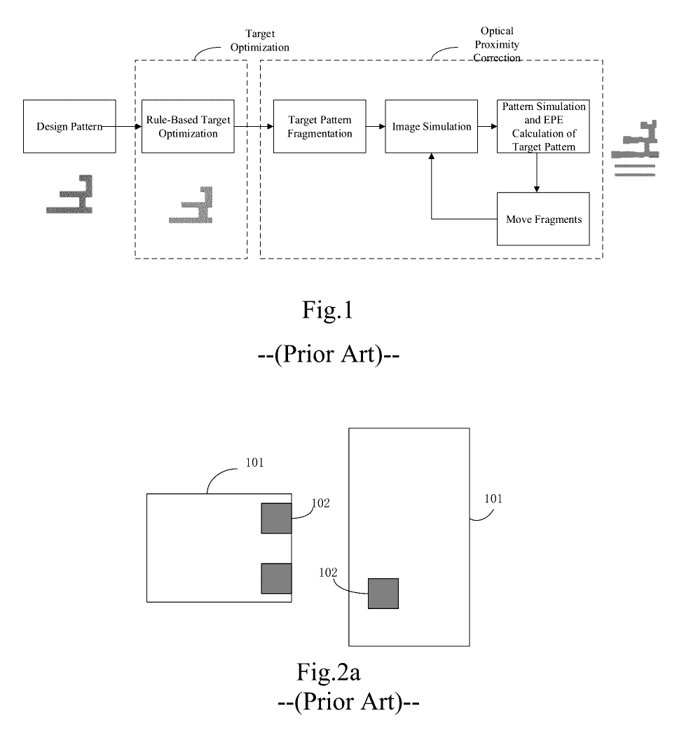

FIG. 2a˜2d are structure schematic diagrams illustrating the metal wires and vias when the conventional target optimization and optical proximity correction processes are applied to a metal layer;

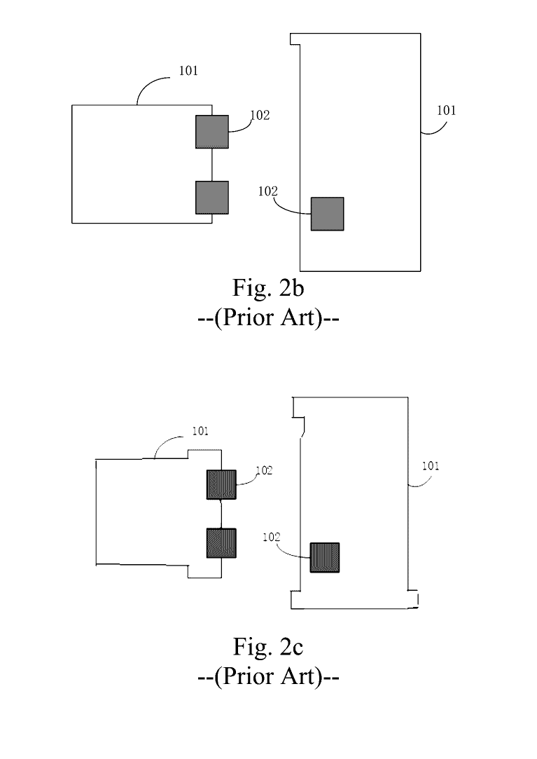

FIG. 3 is a flowchart of a method integrating target optimization and optical proximity correction in an embodiment of the present invention;

FIG. 4 shows the results of processed target pattern obtained under varying process conditions by using the conventional method and the method of the present invention.

FIG. 5 shows the improvement on contact enclosure under single condition simulation.

### DETAILED DESCRIPTION OF THE EMBODIMENTS

Reference will now be made in detail to the present preferred embodiments to provide a further understanding of the invention. The specific embodiments and the accompanying drawings discussed are merely illustrative of specific ways to make and use the invention, and do not limit the scope of the invention or the appended claims.

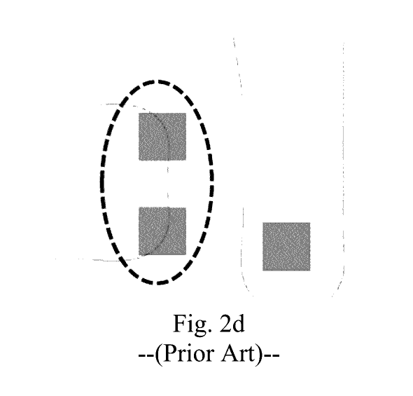

The integrated target optimization and optical proximity correction method of the present invention will be described in further details hereinafter with respect to an embodiment and the accompany drawing FIG. 3.

FIG. 3 is a flow chart illustrating the integrated target optimization and optical proximity correction method which comprises the following steps:

Step S01: inputting a design pattern, wherein, the design pattern includes at least a metal layer and a via layer.

Step S02: fragmenting sides of a target pattern in the metal layer to form a plurality of fragments. In this step, for example, the sides of the target pattern are fragmented according to specified rules.

Next, calculating a target pattern optimal parameter (CDSE) for each fragment. In the target optimization process of the present invention, the target pattern optimal parameter is used to optimize the target pattern, and it is affected by three parameters related to the fragment: image log slope (ILS) of the fragment; the ratio of a portion of an overlap between the target pattern and a via pattern of the via layer which corresponds to the fragment, to a portion of the via pattern which corresponds to the fragment (Enclosure); and the critical dimension (CD) of the fragment;

In the photolithography process, Dose (exposure energy) and Focus error are the two main conditions affecting the lithography process, wherein the Focus error (Δf) originates from the fluctuations of the image plane, these fluctuations come from wafer flatness, lens aberrations, etc. The exposure energy error (Δd) in the optical proximity correction model is approximately equivalent to the change in incident light intensity (ΔI). The more rapidly the intensity of the incident light changes, the clearer the definition of the pattern contour is, so that better control over the critical dimension of the lithographic pattern can be achieved. The optical image edge aberration (Δx), which is caused by the variation in incident light intensity, can be represented by an image slope (ΛI) as follows.

$$Δ x = Δ {d [ \frac{\partial I}{\partial x} {\vert}_{x = \frac{CD}{2} \cdot {f}_{nom}} ]}^{- 1} = \frac{Δ d}{∇ I}$$

Wherein the fₙₒₘ is the optimal focal length, the CD is critical dimension, the image slope (ΛI) is the imaging variation (Δx) caused by a relatively small changes in exposure energy (ΔI) and is approximate estimated as ΔI/Δx. Thus, the image log slope (ILS) can be represented as

$$ILS = \frac{1}{I} \frac{\partial I}{\partial x} .$$

The above formula shows that the higher the image log slope, the lower the sensitivity of critical dimension variation (Δx) to the exposure energy changes (Δd), which will achieve better imaging stability, and greater process window.

Therefore, on one hand, when optimizing the target pattern, step S03 is performed at first to simulate the target pattern and calculate the image log slope (ILS) for each fragment. In this step, preferably, the target pattern is simulated by using a model which is same as an OPC model used in the subsequent optical proximity correction process. The target pattern is simulated with small variation in the exposure energy (ΔI) respectively to obtain the edge aberration (Δx) of the simulated target pattern, whereby the image log slope of each fragment is obtained.

On the other hand, as described in the background of the invention, in the target optimization process for the metal layer, without considering the interconnection between the metal layer and the via layer, it may cause localized interconnection failures between the metal wires and the vias or smaller interconnection process window. Therefore, the present invention considers ‘Enclosure’ (overlap ratio of wire and vias) as a measure of the target pattern optimization. The parameter ‘Enclosure’ is the ratio of an overlapping portion of the target pattern and the via pattern to the via pattern, which is represented as Enclosure

$$= \frac{\begin{matrix}portion of anoverlap between the target pattern \\ and the via pattern corresponding to the fragment\end{matrix}}{\begin{matrix}portion of the via pattern corresponding \\ to the fragment\end{matrix}} \times$$

100%. Under normal circumstances with no target pattern optimization, the ‘Enclosure’ value should be 100%. During the process of target optimization, if the fragment of the metal wire moves outwards the pattern, the ‘Enclosure’ of the fragment will be maintained at 100%; on the other hand, if the fragment moves inwards the pattern, the ‘Enclosure’ of the fragment may be reduced.

In addition, the critical dimension (CD) of each fragment is the third factor affecting the target pattern optimization. Wherein, the critical dimension includes a line-width of the metal wire corresponding to the fragment (width) and the spacing between the metal wire corresponding to the fragment and its adjacent metal wire.

Step S04, calculating a target pattern optimal parameter (CDSE) for each fragment based on the three parameters mentioned above.

The target pattern optimal parameter (CDSE) for each fragment is a product of three parameters: the image log slope (ILS); the ratio of the overlapping portion of the target pattern and the via pattern to the via pattern (Enclosure); and the critical dimension (CD). The equation can be written as:

CDSE=CD×ILS×Enclosure

Since the critical dimension of the fragment has two different parameters, the width and the space, each fragment would have two target pattern optimal parameter values respectively, that is, a line-width parameter (WCDSE=CDwidth×ILS×Enclosure) and a spacing parameter (SCDSE=CDspace×ILS×Enclosure).

As known from above, the target pattern optimal parameters (CDSE) of the present invention is calculated based on three parameters, therefore, it is relatively reliable to use the CDSE value to determine the process window, and to optimize the target pattern in order to improve the process window.

Next, step S05, optimizing the target pattern based on the target pattern optimal parameter (CDSE) for each fragment.

This step is performed by using a look-up table, which constitutes the target pattern optimal parameters (CDSE), to move every fragment in order to optimize the target pattern. More specifically, firstly, a look-up table recording retargeting values of the fragments with different combinations of line-width (WCDSE) and spacing (SCDSE) parameters, as shown in Table I (Table I only shows the trend values of WCDSE and SCDSE, specific values are not shown), is established. The retargeting values can be obtained by performing multiple experiments using different combinations of WCDSE and SCDSE parameters.

TABLE 1

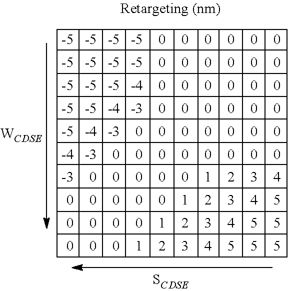

Then, moving each fragment based on the retargeting value obtained from the look-up table which corresponds to the line-width (WCDSE) and spacing (SCDSE) parameters of the fragment. The negative value indicates that the fragment should be moved inwards the pattern, the positive value indicates that the fragment should be moved outwards the pattern, thus to complete the target pattern optimization.

After the target optimization, the optical proximity correction (step S06) is performed. The OPC process comprises simulating the optimized target pattern, and moving each fragment based on the edge placement error (EPE) between the simulation contour and the optimized target pattern, thus to complete the optical proximity correction. Wherein, the mid-point of each fragment can be used as an evaluation point. When EPE is a positive value (simulated pattern beyond the evaluation point), the fragment should be moved inwards the pattern; and vice versa, when EPE is a negative value, the fragment should be moved outwards the pattern. Preferably, the simulation of the target pattern in this step and the simulation in the step S03 are based on the same OPC model, so as to reduce the impact on overall imaging processing time.

Step S03 to step S06 shows one iteration of the method integrating target pattern optimization and optical proximity correction according to the present invention. When an iteration is completed, it is determined whether the corrected target pattern meets requirements, if yes, ending the target optimization and optical proximity correction; if no, then performing the next iteration, that is, using the corrected target pattern as a current target pattern and repeat step S03 to step S06. The target pattern is iterated several times until the resulting pattern meets the requirements (S07). In this embodiment, whether the corrected target pattern meets the requirements is determined by considering whether the edge placement error between the simulation contour and the corrected target pattern is less than a predetermined threshold.

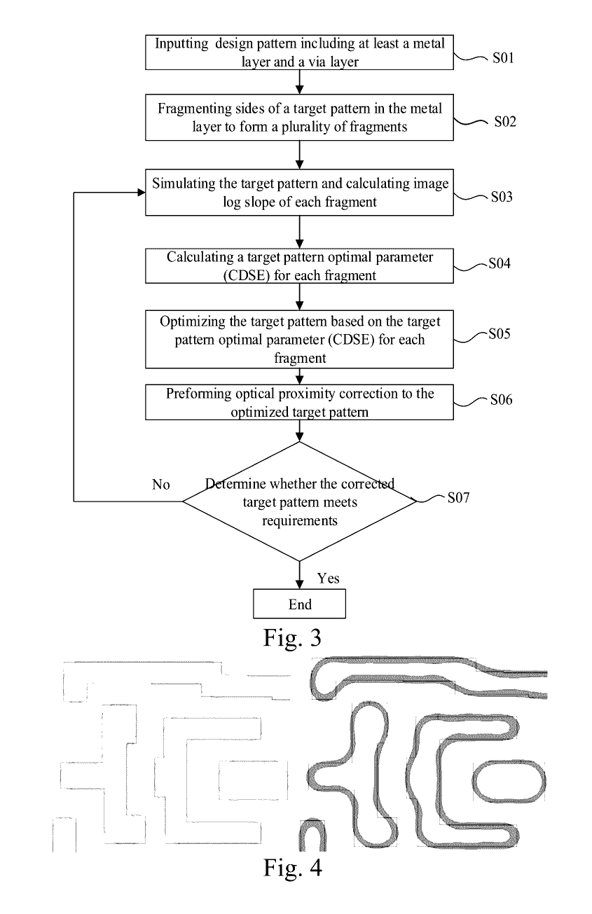

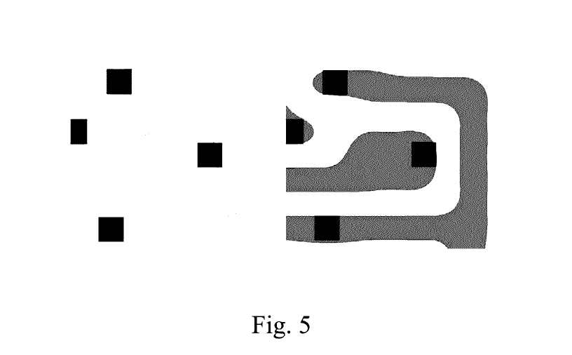

FIG. 4 shows the results of simulation based on the same OPC model under varying process conditions, the left picture shows the simulation results by using the conventional method, the right picture shows the simulation results by using the method of the present invention, and the bandwidth (band) represents the range of OPC simulation results under varying process conditions. As shown in the figure, the sensitivity of the optimized target pattern is reduced significantly to varying process conditions; the process window has been significantly improved. FIG. 5 shows the improvement on contact enclosure under single condition simulation, the left picture shows the simulation results by using the conventional method, and the right picture shows the simulation results by using the method of the present invention. As shown in the figure, some contact's enclosure condition is improved with present invention.

In summary, compared with the conventional rule-based target pattern optimization method, the target optimization process and optical proximity correction process of the present invention are both model-based, which has better expansibility and accuracy, and also can be applied to a variety of complex patterns of two-dimensional structure. Furthermore, the method integrating target optimization and optical proximity correction of the present invention improves the photolithographic process window by reducing the sensitivity of localized pattern to varying process conditions.

Although the present invention has been disclosed as above with respect to the preferred embodiments, they should not be construed as limitations to the present invention. Various modifications and variations can be made by the ordinary skilled in the art without departing the spirit and scope of the present invention. Therefore, the protection scope of the present invention should be defined by the appended claims.

1. A method integrating target optimization and optical proximity correction comprising the following steps:
Step S01: inputting a design pattern which includes at least a metal layer and a via layer;
Step S02: fragmenting sides of a target pattern in the metal layer to form a plurality of fragments;
Step S03: simulating the target pattern and calculating image log slope of each fragment;
Step S04: calculating a target pattern optimal parameter for each fragment, wherein the target pattern optimal parameter is a product of three parameters including the image log slope of the fragment, a ratio of a portion of an overlap between the target pattern and a via pattern in the via layer which corresponds to the fragment to a portion of the via pattern which corresponds to the fragment; and a critical dimension of the fragment;
Step S05: optimizing the target pattern based on the target pattern optimal parameter for each fragment;
Step S06: preforming optical proximity correction to the optimized target pattern;
Step S07: determining whether the corrected target pattern meets requirements; if yes, ending the target optimization and optical proximity correction; otherwise, using the corrected target pattern as a current target pattern and iterate from the step S03.

2. The method according to claim 1, wherein the critical dimension of the fragment includes line-width of the target pattern corresponding to the fragment and spacing between the target pattern and its adjacent pattern corresponding to the fragment.

3. The method according to claim 2, wherein the target pattern optimal parameter for each fragment includes a line-width parameter and a spacing parameter.

4. The method according to claim 3, wherein in the step S05, the target pattern is optimized by moving each fragment according to a look-up table which constitutes the target pattern optimal parameters of each fragment.

5. The method according to claim 4, wherein the step S05 comprises:
establishing a look-up table recording retargeting values of the fragments with different combinations of line-width and spacing parameters; and moving each fragment the retargeting value corresponding to the line-width and the spacing parameters of the fragment recorded in the look-up table.

6. The method according to claim 1, wherein in the step S04, the target pattern optimal parameter of each fragment is calculated based on a mid-point of the fragment.

7. The method according to claim 1, wherein in the step S02, the target pattern is fragmented according to specified rules.

8. The method according to claim 1, wherein the step S06 comprises: simulating the optimized target pattern at 1^{st} iteration or corrected pattern at other iterations; and moving each fragment based on an edge placement error between the simulation contour and the optimized target pattern.

9. The method according to claim 1, wherein in the step S07, whether the corrected target pattern meets the requirements is determined through determining whether the edge placement error between the simulation contour of the corrected target pattern after simulating once again and the contour of the corrected target pattern is less than a predetermined threshold.

10. The method according to claim 8, wherein in the step S06, the optimized target pattern is simulated based on a model which is the same as a model used in the step 03 for simulating the target pattern.

11. The method according to claim 2, wherein in the step S07, whether the corrected target pattern meets the requirements is determined through determining whether the edge placement error between the simulation contour of the corrected target pattern after simulating once again and the contour of the corrected target pattern is less than a predetermined threshold.

12. The method according to claim 3, wherein in the step S07, whether the corrected target pattern meets the requirements is determined through determining whether the edge placement error between the simulation contour of the corrected target pattern after simulating once again and the contour of the corrected target pattern is less than a predetermined threshold.

13. The method according to claim 4, wherein in the step S07, whether the corrected target pattern meets the requirements is determined through determining whether the edge placement error between the simulation contour of the corrected target pattern after simulating once again and the contour of the corrected target pattern is less than a predetermined threshold.

14. The method according to claim 5, wherein in the step S07, whether the corrected target pattern meets the requirements is determined through determining whether the edge placement error between the simulation contour of the corrected target pattern after simulating once again and the contour of the corrected target pattern is less than a predetermined threshold.

15. The method according to claim 6, wherein in the step S07, whether the corrected target pattern meets the requirements is determined through determining whether the edge placement error between the simulation contour of the corrected target pattern after simulating once again and the contour of the corrected target pattern is less than a predetermined threshold.

16. The method according to claim 7, wherein in the step S07, whether the corrected target pattern meets the requirements is determined through determining whether the edge placement error between the simulation contour of the corrected target pattern after simulating once again and the contour of the corrected target pattern is less than a predetermined threshold.

17. The method according to claim 8, wherein in the step S07, whether the corrected target pattern meets the requirements is determined through determining whether the edge placement error between the simulation contour of the corrected target pattern after simulating once again and the contour of the corrected target pattern is less than a predetermined threshold.
